(19) United States
(12) Patent Application Publication
(10) Pub. No.: US 2025/0166707 A1
(43) Pub. Date: May 22, 2025

(54) MEMORY DEVICE AND STORAGE DEVICE INCLUDING THE SAME

(71) Applicant: SK hynix Inc., Icheon-si Gyeonggi-do (KR)

(72) Inventor: Byoung Young KIM, Icheon-si Gyeonggi-do (KR)

(73) Assignee: SK hynix Inc., Icheon-si Gyeonggi-do (KR)

(21) Appl. No.: 18/623,588

(22) Filed: Apr. 1, 2024

(30) Foreign Application Priority Data
Nov. 16, 2023 (KR) 10-2023-0159009

(51) Int. Cl. G11C 16/10; G11C 16/26

(52) U.S. Cl. CPC G11C 16/102; G11C 16/26

(57) ABSTRACT

A memory device includes a plurality of memory cells; and a peripheral unit configured to store k bits in each of the memory cells by controlling the memory cells to form 2^{k-1}+1 threshold voltage distributions, k being an integer.

### CROSS-REFERENCES TO RELATED APPLICATION

The present application claims priority under 35 U.S.C. § 119 (a) to Korean application number 10-2023-0159009, filed on Nov. 16, 2023, in the Korean Intellectual Property Office, which application is incorporated herein by reference in its entirety.

### BACKGROUND

### 1. Technical Field

The present disclosure relates to a memory device.

### 2. Related Art

A storage device may be configured to store data, provided from an external device, in response to a write request from the external device. The storage device may also be configured to provide the stored data to the external device in response to a read request from the external device. The external device is an electronic device capable of processing data and may include a computer, a digital camera, a mobile phone, and the like. The storage device may operate by being embedded in the external device or may be manufactured in a detachable form and operate by being connected to the external device.

The storage device may include a memory device for storing data. The memory device may include a plurality of memory cells and may program data into the memory cell by controlling a threshold voltage of the memory cell. The memory device may also read data from the memory cell by determining the threshold voltage of the memory cell. In order to improve the execution speed of the program operation and the read operation of the memory device, a new technology method may be required.

### SUMMARY

A memory device in accordance with an embodiment of the present disclosure may include: a plurality of memory cells; and a peripheral unit configured to store k bits in each of the memory cells by controlling the memory cells to form 2^{k-1}+1 threshold voltage distributions, wherein k is an integer.

A memory device in accordance with an embodiment of the present disclosure may include: a plurality of memory cells; and a peripheral unit configured to control the plurality of memory cells to form n number of threshold voltage distributions when k bits are stored in each of the plurality of memory cells during a normal program operation and configured to control the plurality of memory cells to form m number of threshold voltage distributions when k bits are stored in each of the plurality of memory cells during a fast program operation, wherein n is greater than m, and wherein k, n, and m are integers.

A storage device in accordance with an embodiment of the present disclosure may include: a controller configured to convert first data into second data, the controller converting, in the first data, a bit at a predetermined position among k bits corresponding to each of a plurality of even-numbered memory cells, among a plurality of target memory cells, into a first value and converting a bit at the predetermined position, among k bits corresponding to each of a plurality of odd-numbered memory cells among the plurality of target memory cells into a second value, the second value being different from the first value; and a memory device configured to store the second data in the plurality of target memory cells under the control of the controller, wherein k is an integer.

### BRIEF DESCRIPTION OF THE DRAWINGS

FIG. 1 is a block diagram illustrating a memory device in accordance with an embodiment.

FIG. 2 is a circuit diagram illustrating a memory block in accordance with an embodiment.

FIG. 3 is a diagram illustrating threshold voltage distributions of target memory cells formed through a normal program operation in accordance with an embodiment.

FIG. 4 is a diagram illustrating threshold voltage distributions of target memory cells formed through a fast program operation in accordance with an embodiment.

FIG. 5 is a diagram illustrating threshold voltage distributions of even-numbered memory cells and threshold voltage distributions of odd-numbered memory cells after a fast program operation has been performed in accordance with an embodiment.

FIG. 6 is a diagram illustrating a method for performing a fast read operation on target memory cells on which a fast program operation has been performed in accordance with an embodiment.

FIG. 7 is a diagram illustrating a method for performing a fast program operation and a fast read operation when other data patterns correspond to threshold voltage distributions in accordance with an embodiment.

FIG. 8 is a block diagram illustrating a storage device including the memory device of FIG. 1 in accordance with an embodiment.

FIG. 9 is a diagram illustrating an operation of the storage device when a bit at a predetermined position converted by a conversion unit of FIG. 8 in accordance with an embodiment is a CSB.

### DETAILED DESCRIPTION

Hereinafter, embodiments of the present disclosure are described in detail with reference to the drawings.

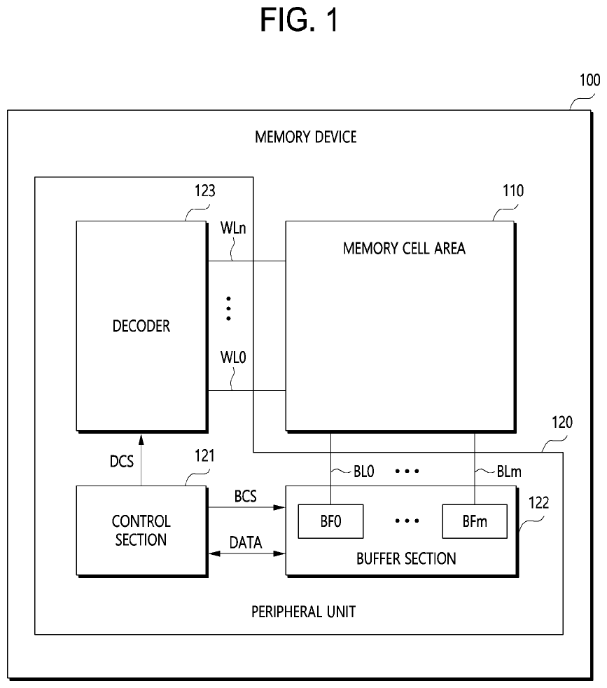

FIG. 1 is a block diagram illustrating a memory device 100 in accordance with an embodiment.

Referring to FIG. 1, the memory device 100 may operate under the control of an external device, for example, a controller. The memory device 100 may store data under the control of the controller.

The memory device 100 may include various types of memories, such as a NAND flash memory, a 3-dimensional (D) NAND flash memory, a NOR flash memory, a resistive random access memory (RRAM), a phase-change random access memory (PRAM), a magnetoresistive random access memory (MRAM), a ferroelectric random access memory (FRAM), or a spin transfer torque random access memory (STT-RAM)

The memory device 100 may include a memory cell area 110 and a peripheral unit 120.

The memory cell area 110 may include a plurality of memory cells for storing data. The memory cells may be accessed by the peripheral unit 120 through word lines WL0 to WLn and bit lines BL0 to BLm.

The peripheral unit 120 may store data in the memory cell area 110 by performing a program operation on the memory cell area 110 under the control of the controller. The program operation may include a normal program operation and a fast program operation. The peripheral unit 120 may read data from the memory cell area 110 by performing a read operation on the memory cell area 110 under the control of the controller. The read operation may include a normal read operation and a fast read operation.

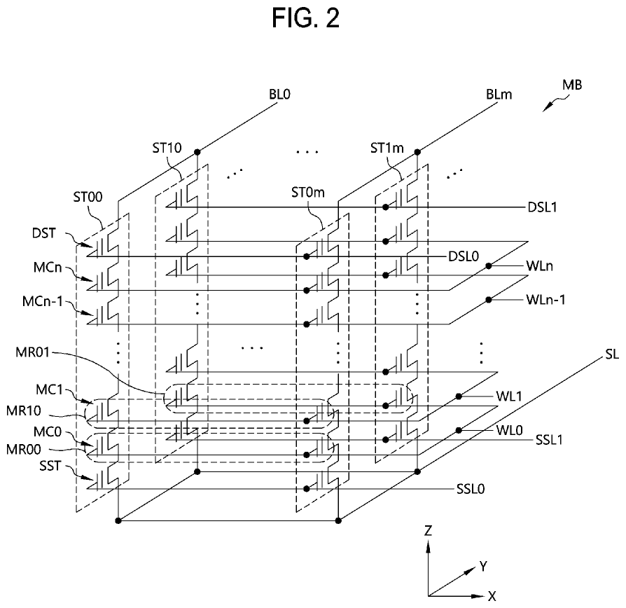

Specifically, the peripheral unit 120 may control target memory cells to form 2^{k} threshold voltage distributions through a normal program operation, thereby storing k bits in each of the target memory cells. The target memory cells may be memory cells connected to a target word line selected from the word lines WL0 to WLn. The target memory cells may be memory cells included in one memory area, as described below with reference to FIG. 2.

The peripheral unit 120 may also read k bits from each of the target memory cells through a normal read operation. The peripheral unit 120 may perform a normal read operation based on 2^{k-1} read voltages located between 2^{k} threshold voltage distributions.

The peripheral unit 120 may also perform a fast program operation that is faster than the normal program operation. Specifically, the peripheral unit 120 may store k bits in each of the memory cells by controlling the target memory cells to form 2^{k-1}+1 threshold voltage distributions through the fast program operation.

More specifically, in the fast program operation, when the k bits to be stored in the target memory cell are erase values, the peripheral unit 120 may control the target memory cell to be located in the lowest threshold voltage distribution, among the 2^{k-1}+1 threshold voltage distributions. In the present disclosure, the erase value may mean a bit value stored in a memory cell in an erased state, for example, 1.

In the fast program operation, when a bit at a predetermined position, among the k bits to be stored in the target memory cell, is a complement to the erase value and the remaining bits, which are the k bits excluding the bit at the predetermined position, are erase values, the peripheral unit 120 may control the target memory cell to be located in the second lowest threshold voltage distribution, among the 2^{k-1}+1 threshold voltage distributions.

In the fast program operation, when at least one of the remaining bits, which are the k bits excluding the bit at the predetermined position, among the k bits to be stored in the target memory cell, is a complement to the erase value, the peripheral unit 120 may control the target memory cell to be located in any one of the remaining threshold voltage distributions, which are the 2^{k-1}+1 threshold voltage distributions excluding the lowest and second lowest threshold voltage distributions, according to the remaining bits.

After the fast program operation has been performed, first memory cells, among the target memory cells, may form the remaining threshold voltage distributions, which are the 2^{k-1}+1 threshold voltage distributions excluding the second lowest threshold voltage distribution. According to the remaining bits, which are the k bits excluding the bit at the predetermined position, each of the first memory cells may be located in any of the remaining threshold voltage distributions, which are the 2^{k-1}+1 threshold voltage distributions excluding the second lowest threshold voltage distribution.

After the fast program operation has been performed, second memory cells, among the target memory cells, may form the remaining threshold voltage distributions, which are the 2^{k-1}+1 threshold voltage distributions excluding the lowest threshold voltage distribution. According to the remaining bits, which are the k bits excluding the bit at the predetermined position, each of the second memory cells may be located in any of the remaining threshold voltage distributions, which are 2^{k-1}+1 threshold voltage distributions excluding the lowest threshold voltage distribution.

The second memory cells on which the fast program operation has been performed may be the remaining memory cells, which are the target memory cells excluding the first memory cells. Depending on the embodiment, the first memory cells may be memory cells (that is, even-numbered memory cells) connected to even-numbered bit lines, and the second memory cells may be memory cells (that is, odd-numbered memory cells) connected to odd-numbered bit lines. The even-numbered bit line may be a bit line corresponding to an even-numbered column address, and the odd-numbered bit line may be a bit line corresponding to an odd-numbered column address. Depending on the embodiment, the first memory cells may be odd-numbered memory cells and the second memory cells may be even-numbered memory cells.

Among the k bits to be stored in each of the first memory cells through the fast program operation, a bit at the predetermined position may be fixed as an erase value. Among the k bits to be stored in each of the second memory cells through the fast program operation, a bit at the predetermined position may be fixed as a complement to the erase value. The memory device 100 may receive such data from the controller in conjunction with a command for the fast program operation.

The peripheral unit 120 may also perform a fast read operation that is faster than the normal read operation. After the fast program operation has been performed, the peripheral unit 120 may perform a fast read operation on the target memory cells, which forms the 2^{k-1}+1 threshold voltage distributions. Specifically, in the fast read operation, the peripheral unit 120 may read the k bits stored in each of the target memory cells based on 2^{k-1} read voltages, each located between the 2^{k-1}+1 threshold voltage distributions.

More specifically, the peripheral unit 120 may apply the remaining read voltages, which are the 2^{k-1} read voltages excluding the lowest read voltage, to the target memory cells and may read the remaining bits stored in each of the target memory cells, which are the k bits excluding the bit at the predetermined position, according to the result of comparing a threshold voltage of each of the target memory cells with read voltages.

The peripheral unit 120 may apply the lowest read voltage, among the 2^{k-1} read voltages, to the target memory cells and may read a bit at the predetermined position, among the k bits, stored in each of the second memory cells, among the target memory cells, according to the result of comparing a threshold voltage of each of the second memory cells with the lowest read voltage.

Regardless of the result of applying the lowest read voltage, among the 2^{k-1} read voltages, to the target memory cells, the peripheral unit 120 may read, as an erase value, a bit at the predetermined position, among the k bits stored, in each of the first memory cells, among the target memory cells.

In summary, although the fast program operation stores data with the same size as data stored through the normal program operation, the fast program operation forms fewer threshold voltage distributions than the normal program operation which results in the fast program operation being performed more quickly than the normal program operation. Furthermore, although the fast read operation reads data with the same size as data read through the normal read operation, the fast read operation uses fewer read voltages than the normal read operation which also results in the fast read operation being performed more quickly than the normal read operation. Accordingly, according to the present disclosure, the memory device 100 may provide improved operating performance through the fast program operation and the fast read operation.

The peripheral unit 120 may include a control section 121, a buffer section 122, and a decoder 123. Each of the control section 121, the buffer section 122, and the decoder 123 may include hardware, software, firmware, or a combination thereof.

The control section 121 may control the operations of the buffer section 122 and the decoder 123 in order to access the memory cell area 110 under the control of the controller. For example, in order to control the buffer section 122, the control section 121 may generate buffer control signals BCS and may output the buffer control signals BCS to the buffer section 122. The control section 121 may transmit data DATA to be stored in the memory cell area 110 to the buffer section 122 and may receive, from the buffer section 122, data DATA read from the memory cell area 110. In order to control the decoder 123, the control section 121 may generate decoder control signals DCS and may output the decoder control signals DCS to the decoder 123. The decoder control signals DCS may include predetermined voltages (for example, program voltages, read voltages, and the like) to be applied to the word lines WL0 to WLn. Although not illustrated, the control section 121 may include an interface configured to communicate with the controller and a voltage generation circuit configured to generate various voltages.

The buffer section 122 may be connected to the memory cell area 110 through the bit lines BL0 to BLm. The buffer section 122 may include a plurality of sub-buffers BF0 to BFm connected to the bit lines BL0 to BLm, respectively. The sub-buffers BF0 to BFm may be connected to the memory cells included in the memory cell area 110 through the bit lines BL0 to BLm. The sub-buffers BF0 to BFm may receive the data DATA to be stored in the memory cells from the control section 121 and may store the received data DATA. The sub-buffers BF0 to BFm may store the data DATA read from the memory cells, and the stored data DATA may be transmitted to the control section 121. Each of the sub-buffers BF0 to BFm may perform a sensing operation that senses a voltage or a current formed in a corresponding bit line as the corresponding memory cell is turned on/off in response to a read voltage. The sub-buffers BF0 to BFm may simultaneously operate in response to the buffer control signals BCS, and thus, memory cells respectively connected to the bit lines BL0 to BLm may be simultaneously accessed.

The decoder 123 may be connected to the memory cell area 110 through the word lines WL0 to WLn. The decoder 123 may apply predetermined voltages to the word lines WL0 to WLn when a program operation, a read operation, and the like are performed.

FIG. 2 is a circuit diagram illustrating a memory block MB in accordance with an embodiment. The memory cell area 110 in FIG. 1 may include a plurality of memory blocks configured similarly to the memory block MB.

Referring to FIG. 2, the memory block MB may be connected to the peripheral unit 120 through word lines WL0 to WLn, bit lines BL0 to BLm, select lines DSL0, DSL1, SSL0, and SSL1, and a source line SL.

The memory block MB may include strings ST00 to ST0m and ST10 to ST1m. Each of the strings ST00 to ST0m and ST10 to ST1m may extend along a vertical direction (Z direction). Within the memory block MB, m strings may be arranged in a row direction (X direction). FIG. 2 illustrates that two strings are arranged in a column direction (Y direction); however, this is for convenience of explanation, and three or more strings may be arranged in the column direction (Y direction).

The strings ST00 to ST0m and ST10 to ST1m may be identically configured. For example, the string ST00 may include a source select transistor SST, memory cells MC0 to MCn, and a drain select transistor DST connected in series between the source line SL and the bit line BL0. A source of the source select transistor SST may be connected to the source line SL, and a drain of the drain select transistor DST may be connected to the bit line BL0. The memory cells MC0 to MCn may be connected in series between the source select transistor SST and the drain select transistor DST. Depending on the embodiment, a plurality of source select transistors may be connected in series between the source line SL and the memory cell MC0. Depending on the embodiment, a plurality of drain select transistors may be connected in series between the bit line BL0 and the memory cell MCn.

Source select transistors at substantially the same position in the vertical direction may be configured as follows. Specifically, gates of source select transistors of strings arranged in substantially the same row may be connected to substantially the same source select line. For example, the gates of source select transistors of the strings ST00 to ST0m in a first row may be connected to the source select line SSL0. For example, the gates of source select transistors of the strings ST10 to ST1m in a second row may be connected to the source select line SSL1.

Depending on the embodiment, source select transistors of strings in two or more rows may be connected in common to one source select line. For example, the source select transistors of the strings ST00 to ST0m and ST10 to ST1m in the first and second rows may be connected in common to one source select line, and the source select transistors of strings in third and fourth rows may be connected in common to one source select line.

Drain select transistors at substantially the same position in the vertical direction may be configured as follows. Specifically, the gates of drain select transistors of strings arranged in substantially the same row may be connected to substantially the same drain select line. For example, the gates of drain select transistors of the strings ST00 to ST0m in the first row may be connected to the drain select line DSL0. For example, the gates of drain select transistors of the strings ST10 to ST1m in the second row may be connected to the drain select line DSL1.

Strings arranged in substantially the same column may be connected to substantially the same bit line. For example, the strings ST00 and ST10 in a first column may be connected to the bit line BL0. For example, the strings ST0m and ST1m in an m^{th} column may be connected to the bit line BLm.

Gates of memory cells at substantially the same position in the vertical direction may be connected to substantially the same word line. For example, memory cells located at substantially the same position in the vertical direction as the memory cell MC0 in the strings ST00 to ST0m and ST10 to ST1m may be connected to the word line WL0.

Among the memory cells, memory cells connected to substantially the same word line in substantially the same row may form one memory area. For example, memory cells connected to the word line WL0 in the first row may form one memory area MRO0. For example, memory cells connected to the word line WL0 in the second row may form one memory area MR01. For example, memory cells connected to the word line WL1 in the first row may form one memory area MR10. Depending on the number of rows, each word line may be connected to a plurality of memory areas. Memory cells constituting one memory area may be simultaneously accessed.

Depending on the embodiment, the memory block MB may be further connected to one or more dummy word lines other than the word lines WL0 to WLn. In such a case, the memory block MB may further include dummy memory cells connected to dummy word lines.

The memory cell may store one or more bits. A memory cell that stores one bit may be referred to as a single level cell SLC, and a memory area and a memory block including SLCs may be referred to as an SLC memory area and an SLC memory block, respectively. A memory cell storing a plurality of bits may be referred to as an extra level cell XLC, and a memory area and a memory block including XLCs may be referred to as an XLC memory area and an XLC memory block, respectively. The XLC may include a multi-level cell (MLC), a triple level cell (TLC), a quad level cell (QLC), and the like. The number of bits to be stored in the memory cell (that is, SLC, MLC, TLC, QLC, or XLC to be used as the memory cell) may be changed by the controller.

One memory area including memory cells each storing k bits may logically include k sub-areas, in other words, pages. For example, the triple level cell (TLC) memory area including TLCs may logically include three pages, that is, a least significant bit (LSB) page (in other words, the lowest level page) where an LSB is stored, a central significant bit (CSB) page (in other words, an intermediate level page) in which a CSB is stored, and a most significant bit (MSB) page (in other words, the highest level page) where an MSB is stored. For example, the quad level cell (QLC) memory area may logically include four pages, that is, an LSB page where an LSB is stored, a first CSB page (in other words, a first intermediate level page) where a first CSB is stored, a second CSB page (in other words, a second intermediate level page) where a second CSB is stored, and an MSB page where an MSB is stored.

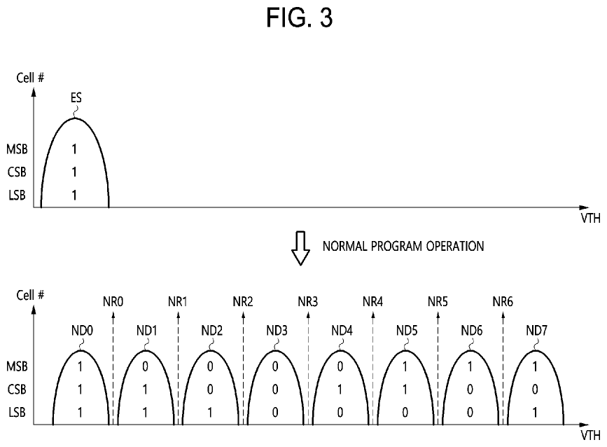

FIG. 3 is a diagram illustrating threshold voltage distributions ND0 to ND7 of target memory cells formed through a normal program operation in accordance with an embodiment. A horizontal axis VTH may represent the threshold voltage of the memory cell, and a vertical axis Cell # may correspond to the number of target memory cells with the corresponding threshold voltages.

Referring to FIG. 3, the target memory cells may be TLCs, for example. The target memory cells may form a threshold voltage distribution ES in an erased state. The target memory cell located in the threshold voltage distribution ES may be in a state in which data 111 is stored. An erase value may mean a value stored in a target memory cell in an erased state, that is, 1.

Target memory cells in an erased state may store data through the normal program operation. The target memory cells may form threshold voltage distributions ND0 to ND7 according to the data stored through the normal program operation. In the normal program operation, each target memory cell may be controlled to be located in any one of the eight threshold voltage distributions ND0 to ND7 according to three bits to be stored in each target memory cell. For example, the target memory cells storing the data 111 may form the threshold voltage distribution ND0, and the target memory cells storing data 011 may form the threshold voltage distribution ND1. Depending on the embodiment, when k bits per target memory cell are stored through the normal program operation, the target memory cells may form 2^{k} threshold voltage distributions.

When a read voltage is applied to a memory cell through a word line, the memory cell may be turned on/off according to a threshold voltage. Specifically, when a read voltage that is higher than the threshold voltage is applied to the memory cell, the memory cell may be turned on, and when a read voltage that is lower than the threshold voltage is applied to the memory cell, the memory cell may be turned off. The memory cell may induce mutually different voltages or currents into a bit line based on whether the memory cell is turned on or turned off, and the memory device 100 may determine whether the threshold voltage of the memory cell is higher or lower than the read voltage by sensing the state of the bit line (that is, a voltage of the bit line or a current flowing through the bit line).

In this way, a normal read operation for target memory cells may be performed using read voltages NR0 to NR6 located between the threshold voltage distributions ND0 to ND7. Specifically, when each of the read voltages NR0 to NR6 is applied to the target memory cell, the memory device 100 may determine whether the threshold voltage of the target memory cell is higher or lower than each of the read voltages NR0 to NR6. As a result, the memory device 100 may determine a threshold voltage distribution in which the target memory cell is located, among the threshold voltage distributions ND0 to ND7, and may determine and output data stored in the target memory cell.

For example, an LSB stored in each target memory cell may be read using the read voltages NR2 and NR6. That is, when the target memory cell has a threshold voltage lower than the read voltage NR2 or higher than the read voltage NR6, 1 may be read from the target memory cell as an LSB. When the target memory cell has a threshold voltage higher than the read voltage NR2 and lower than the read voltage NR6, 0 may be read from the target memory cell as an LSB. In a similar manner, a CSB stored in each target memory cell may be read using the read voltages NR1, NR3, and NR5. An MSB stored in each target memory cell may be read using the read voltages NR0 and NR4.

Depending on the embodiment, when the target memory cells form 2^{k} threshold voltage distributions through the normal program operation, the normal read operation may be performed based on 2^{k}−1 read voltages. In the normal read operation, at least 2^{k}−1 read voltages may be required to distinguish the 2^{k} threshold voltage distributions.

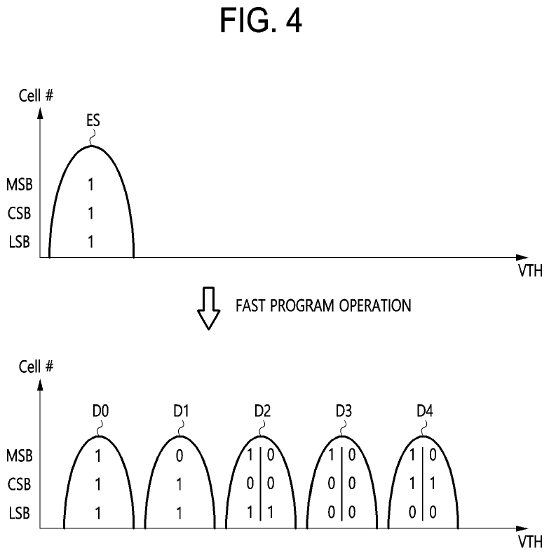

FIG. 4 is a diagram illustrating threshold voltage distributions D0 to D4 of target memory cells formed through a fast program operation in accordance with an embodiment.

Referring to FIG. 4, the memory device 100 may perform the fast program operation on the target memory cells under the control of the controller. The target memory cells may form a threshold voltage distribution ES in an erased state before performing the fast program operation. The target memory cell located in the threshold voltage distribution ES may be in a state in which data 111 is stored.

The target memory cells in an erased state may store data through the fast program operation. The target memory cells may form the threshold voltage distributions DO to D4 according to the data stored through the fast program operation. The peripheral unit 120 may refer to three bits to be stored in the target memory cell in the fast program operation and may control the target memory cell to be located in any one of the five threshold voltage distributions DO to D4.

For example, the target memory cells storing the data 111 through the fast program operation may form the threshold voltage distribution DO. For example, a target memory cell in an erased state may store the data 111 because no threshold voltage is substantially changed in the fast program operation.

Target memory cells storing data 011 through the fast program operation may form the threshold voltage distribution D1. The peripheral unit 120 may store the data 011 in the target memory cell by controlling the target memory cell to have a threshold voltage corresponding to the threshold voltage distribution D1.

Target memory cells storing data 101 or 001 through the fast program operation may form the threshold voltage distribution D2. The peripheral unit 120 may store the data 101 or 001 in the target memory cell by controlling the target memory cell to have a threshold voltage corresponding to the threshold voltage distribution D2. The target memory cell storing the data 101 may be an even-numbered memory cell, and the target memory cell storing the data 001 may be an odd-numbered memory cell.

Target memory cells storing data 100 or 000 through the fast program operation may form the threshold voltage distribution D3. The peripheral unit 120 may store the data 100 or 000 in the target memory cell by controlling the target memory cell to have a threshold voltage corresponding to the threshold voltage distribution D3. The target memory cell storing the data 100 may be an even-numbered memory cell, and the target memory cell storing the data 000 may be an odd-numbered memory cell.

Target memory cells storing data 110 or 010 through the fast program operation may form the threshold voltage distribution D4. The peripheral unit 120 may store the data 110 or 010 in the target memory cell by controlling the target memory cell to have a threshold voltage corresponding to the threshold voltage distribution D4. The target memory cell storing the data 110 may be an even-numbered memory cell, and the target memory cell storing the data 010 may be an odd-numbered memory cell.

Depending on the embodiment, when at least one of a CSB and an LSB to be stored in the target memory cell through the fast program operation is 0, the peripheral unit 120 may determine a threshold voltage distribution to which the target memory cell needs to be located, among the voltage distributions D2 to D4, by referring only to the CSB and the LSB without considering an MSB to be stored in the target memory cell. For example, when the CSB to be stored in the target memory cell is 0 and the LSB to be stored in the target memory cell is 1, the target memory cell needs to be located in the threshold voltage distribution D2 regardless of whether the MSB is 1 or 0. Therefore, the peripheral area 120 might not consider the MSB.

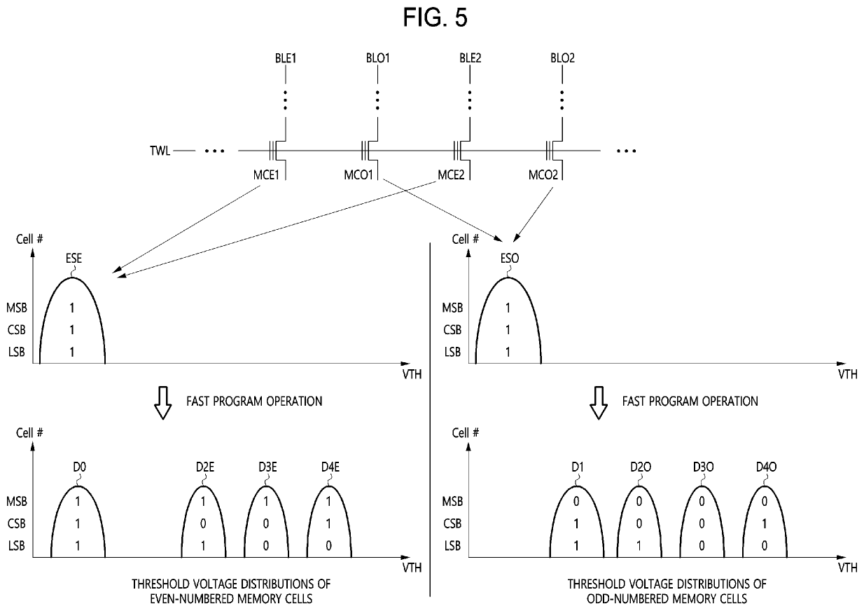

FIG. 5 is a diagram illustrating threshold voltage distributions D0, D2E, D3E, and D4E of even-numbered memory cells MCE1 and MCE2 and threshold voltage distributions D1, D20, D30, and D40 of odd-numbered memory cells MCO1 and MCO2 after a fast program operation has been performed in accordance with an embodiment. The threshold voltage distributions D2E and D20 may be included in the threshold voltage distribution D2 of FIG. 4, the threshold voltage distributions D3E and D30 may be included in the threshold voltage distribution D3 of FIG. 4, and the threshold voltage distributions D4E and D40 may be included in the threshold voltage distribution D4 of FIG. 4. Threshold voltage distributions ESE and ESO may be included in the threshold voltage distribution ES of FIG. 4.

Referring to FIG. 5, data on which the fast program operation is performed may be data converted by the controller depending on whether the data is to be stored in an even-numbered memory cell or an odd-numbered memory cell. The controller may convert a predetermined position, for example, an MSB, into 1 in data to be stored in the even-numbered memory cell and may convert the MSB into 0 in data to be stored in the odd-numbered memory cell.

Accordingly, among target memory cells connected to a target word line TWL, the even-numbered memory cells MCE1 and MCE2 connected to even-numbered bit lines BLE1 and BLE2 may be located in the threshold voltage distribution ESE in an erased state before performing the fast program operation and may be located in the threshold voltage distributions D0, D2E, D3E, and D4E after performing the fast program operation.

Among the target memory cells connected to the target word line TWL, the odd-numbered memory cells MCO1 and MCO2 connected to odd-numbered bit lines BLO1 and BLO2 may be located in the threshold voltage distribution ESO in an erased state before performing the fast program operation and may be located in the threshold voltage distributions D1, D20, D30, and D40 after performing the fast program operation.

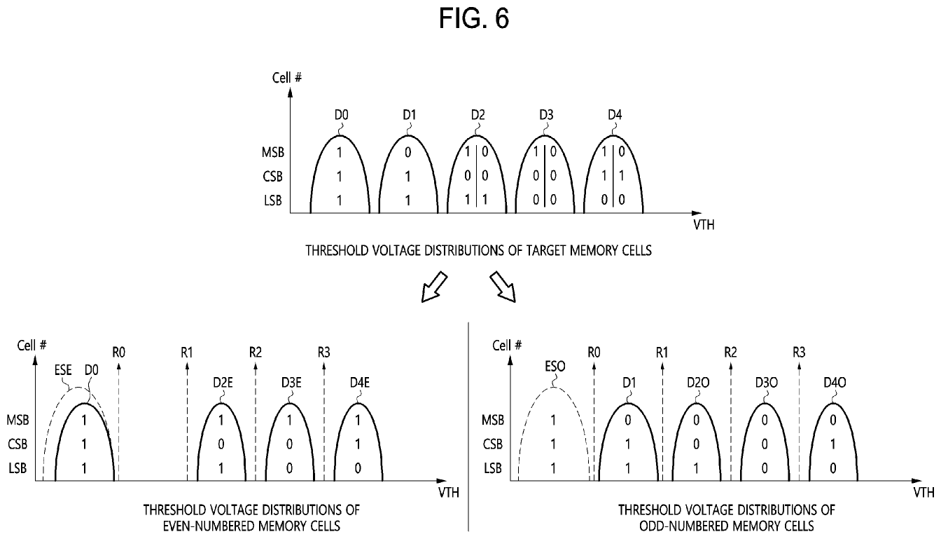

FIG. 6 is a diagram illustrating a method for performing a fast read operation on target memory cells on which a fast program operation has been performed in accordance with an embodiment.

Referring to FIG. 6, the memory device 100 may perform the fast read operation on the target memory cells under the control of the controller. The target memory cells on which the fast read operation is performed may be memory cells on which a fast program operation has been performed. That is, the target memory cells on which the fast read operation is to be performed may be in a state of forming the threshold voltage distributions DO to D4. The memory device 100 may determine data stored in the target memory cell by distinguishing the threshold voltage distributions DO to D4 by using the read voltages R0 to R3 and may output the determined data to the controller. That is, in the fast read operation, only four read voltages may be required to distinguish the five threshold voltage distributions D0 to D4.

In such a case, even though each of the threshold voltage distributions D2 to D4 corresponds to two mutually different data patterns, the memory device 100 may specify data stored in the target memory cell according to whether the target memory cell is an even-numbered memory cell or an odd-numbered memory cell.

Depending on the embodiment, the fast read operation may also be performed on target memory cells in an erased state.

Specifically, the peripheral unit 120 may apply the read voltage R2 to the target memory cells to read an LSB in the fast read operation. The read voltage R2 may be a voltage located between the threshold voltage distributions D2 and D3. The peripheral unit 120 may determine the LSB in a target memory cell to be 1 when the corresponding threshold voltage is lower than the read voltage R2. The peripheral unit 120 may determine the LSB in a target memory cell to be 0 when the corresponding threshold voltage is higher than the read voltage R2.

The peripheral unit 120 may apply the read voltages R1 and R3 to the target memory cells, respectively, to read a CSB in the fast read operation. The read voltage R1 may be a voltage located between the threshold voltage distributions D1 and D2. The read voltage R3 may be a voltage located between the threshold voltage distributions D3 and D4. The peripheral unit 120 may determine the CSB in a target memory cell to be 1 when the corresponding threshold voltage is lower than the read voltage R1 or higher than the read voltage R3. The peripheral unit 120 may determine the CSB in a target memory cell to be 0 when the corresponding threshold voltage is higher than the read voltage R1 and lower than the read voltage R3.

The peripheral unit 120 may apply the read voltage R0 to the target memory cells to read an MSB in the fast read operation. The read voltage R0 may be a voltage located between the threshold voltage distributions D0 and D1. The peripheral unit 120 may determine the MSB in an odd-numbered memory cell to be 1 when the corresponding threshold voltage is lower than the read voltage R0. That is, since the odd-numbered memory cell stores 1 as an MSB when located in the threshold voltage distribution ESO, the MSB of the odd-numbered memory cell in an erased state may be determined using the read voltage R0. The peripheral unit 120 may determine the MSB in an odd-numbered memory cell to be 0 when the corresponding threshold voltage is higher than the read voltage R0.

The peripheral unit 120 may determine the MSB in an even-numbered memory cell to be 1 in the fast read operation. The peripheral unit 120 may determine the MSB in the even-numbered memory cell to be 1, regardless of whether the even-numbered memory cell has a threshold voltage that is lower or higher than the read voltage R0 or any other read voltage. The peripheral unit 120 may determine the MSB in the even-numbered memory cell to be 1, regardless of whether the even-numbered memory cell is in an erased state (that is, located in the threshold voltage distribution ESE) or not. Depending on the embodiment, the peripheral unit 120 might not perform an operation that senses the state of an even-numbered bit line connected to an even-numbered memory cell.

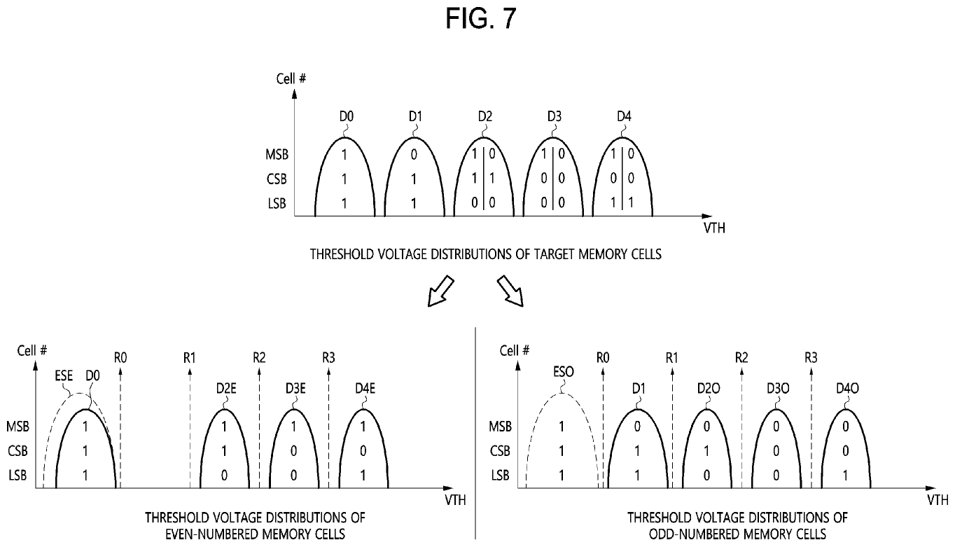

FIG. 7 is a diagram illustrating a method for performing a fast program operation and a fast read operation when different data patterns correspond to the threshold voltage distributions D0 to D4 in accordance with an embodiment.

Referring to FIG. 7, the threshold voltage distributions DO to D4, formed through the fast program operation, may be different from the threshold voltage distributions DO to D4, illustrated in FIG. 4, respectively. For example, data corresponding to the threshold voltage distribution D2 of FIG. 4 may be 101 or 001, but data corresponding to the threshold voltage distribution D2 of FIG. 7 may be 110 or 010.

The peripheral unit 120 may control the target memory cells to form the threshold voltage distributions D0 to D4 of FIG. 7 by performing the fast program operation in a similar manner as described with reference to FIG. 4.

The peripheral unit 120 may perform the fast read operation in a similar manner as described with reference to FIG. 6. For example, in the fast read operation, the peripheral unit 120 may use the read voltage R2 to read a CSB from the target memory cell and use the read voltages R1 and R3 to read an LSB from the target memory cell. In this way, the read voltages for reading the CSB or the LSB may be determined according to data corresponding to the threshold voltage distributions D2 to D4, respectively. The method by which the memory device 100 reads an MSB may be the same as described with reference to FIG. 6.

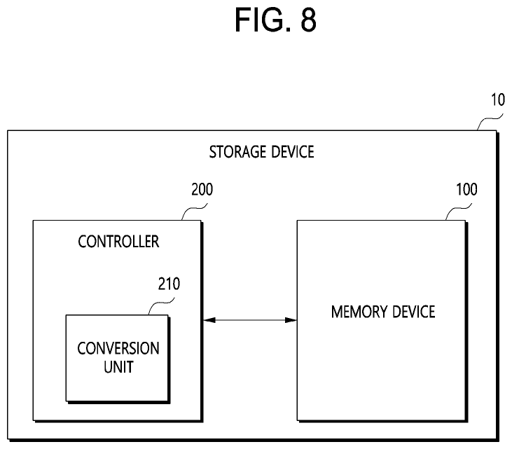

FIG. 8 is a block diagram illustrating a storage device 10 including the memory device 100 of FIG. 1 in accordance with an embodiment.

The storage device 10 may store data received from a host device in response to a write request from an external device, for example, the host device. The storage device 10 may transmit the stored data to the host device in response to a read request from the host device.

The storage device 10 may include a personal computer memory card international association (PCMCIA) card, a smart media card, a memory stick, various multi-media cards such as MMC, eMMC, RS-MMC, and MMC-micro, a secure digital (SD) card such as SD, mini-SD, and micro-SD, a universal flash storage (UFS), or a solid state drive (SSD).

The storage device 10 may include the memory device 100 and a controller 200.

The controller 200 may control the memory device 100 according to a request from the host device. For example, in response to a write request from the host device, the controller 200 may store data transmitted from the host device in the memory device 100. In response to a read request from the host device, the controller 200 may read data from the memory device 100 and transmit the data to the host device.

The controller 200 may control the memory device 100 to perform a normal program operation, a fast program operation, a normal read operation, and a fast read operation.

The controller 200 may include a conversion unit 210 configured to convert first data into second data. The second data may be data to be stored in target memory cells by the memory device 100 through a fast program operation. The controller 200 may convert the first data into the second data and may control the memory device 100 to perform a fast program operation to store the second data. When storing the first data without converting the first data to the second data, the controller 200 may control the memory device 100 to perform a normal program operation to store the first data.

In the first data, the conversion unit 210 may convert a bit at a predetermined position, among k bits to be stored in each of the first memory cells, among the target memory cells, into an erase value, which is 1, and may convert the bit at the predetermined position, among k bits to be stored in each of the second memory cells, among the target memory cells, into a complement of the erase value, which is 0. The first memory cells may be even-numbered memory cells, and the second memory cells may be odd-numbered memory cells, or vice versa. The bit at the predetermined position may be an MSB as in the embodiments of FIGS. 4 to 7 or may be a bit at another position, among the k bits to be stored in the target memory cell. Bits at certain positions to be converted into fixed values by the conversion unit 210 may be determined in advance or may be notified to the memory device 100 by the controller 200.

The controller 200 may further control the memory device 100 to perform the fast read operation to read the second data. The conversion unit 210 may restore the second data transmitted from the memory device 100 to the first data.

Depending on the embodiment, the controller 200 may further include a randomizer (not illustrated) configured to randomize the first data. In such a case, the conversion unit 210 may convert the first data randomized by the randomizer into the second data.

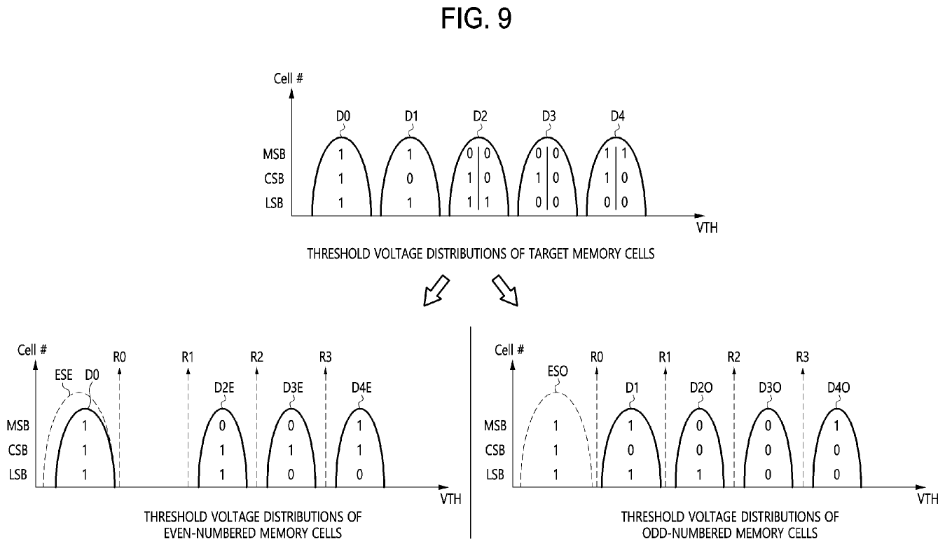

FIG. 9 is a diagram illustrating the operation of the storage device 10 when a bit at a predetermined position converted by the conversion unit 210 in FIG. 8 is a CSB in accordance with an embodiment.

Referring to FIG. 9, the bit at the predetermined position converted by the conversion unit 210 may be a CSB. For example, the conversion unit 210 may convert the CSB of data in each of even-numbered memory cells into 1 and convert the CSB of the data in each of odd-numbered memory cells into 0.

The peripheral unit 120 may control the target memory cells to form the threshold voltage distributions DO to D4 by performing a fast program operation in a similar matter as described with reference to FIG. 4.

The peripheral unit 120 may perform a fast read operation in a similar manner as described with reference to FIG. 6. For example, the peripheral unit 120 may use the read voltage R2 to read an LSB from the target memory cell in the fast read operation. The peripheral unit 120 may use the read voltages R1 and R3 to read an MSB from the target memory cell in the fast read operation. The peripheral unit 120 may use the read voltage R0 to read a CSB from an odd-numbered memory cell. The peripheral unit 120 may determine the CSB in an odd-numbered memory cell to be 1 when the corresponding threshold voltage is lower than the read voltage R0. The peripheral unit 120 may determine the CSB in an odd-numbered memory cell to be 0 when the corresponding threshold voltage is higher than the read voltage R0. The peripheral unit 120 may determine the CSB in an even-numbered memory cell to be 1, regardless of the result of applying any read voltage.

A person skilled in the art to which the present disclosure pertains can understand that the present disclosure may be carried out in other specific forms without changing its technical spirit or essential features. Therefore, it should be understood that the embodiments described above are illustrative in all aspects, not limitative. The scope of the present disclosure is defined by the claims to be described below rather than the detailed description, and it should be construed that all changes or modified forms derived from the meaning and scope of the claims and the equivalent concept thereof are included in the scope of the present disclosure.

What is claimed is:

1. A memory device comprising:
a plurality of memory cells; and
a peripheral unit configured to store k bits in each of the memory cells by controlling the memory cells to form 2^{k-1}+1 threshold voltage distributions,
wherein k is an integer.

2. The memory device according to claim 1, wherein a plurality of first memory cells, among the plurality of memory cells, form remaining threshold voltage distributions, which are the 2^{k-1}+1 threshold voltage distributions excluding a second lowest threshold voltage distribution, and a plurality of second memory cells, among the plurality of memory cells, form remaining threshold voltage distributions, which are the 2^{k-1}+1 threshold voltage distributions excluding a lowest threshold voltage distribution.

3. The memory device according to claim 2, wherein each of the plurality of first memory cells is located in any one of the remaining threshold voltage distributions, which are the 2^{k-1}+1 threshold voltage distributions excluding the second lowest threshold voltage distribution, according to remaining bits, which are the k bits excluding a bit at a predetermined position.

4. The memory device according to claim 2, wherein each of the plurality of second memory cells is located in any one of the remaining threshold voltage distributions, which are the 2^{k-1}+1 threshold voltage distributions excluding the lowest threshold voltage distribution, according to remaining bits, which are the k bits excluding a bit at a predetermined position.

5. The memory device according to claim 2, wherein the first memory cells are even-numbered memory cells, and
wherein the second memory cells are odd-numbered memory cells.

6. The memory device according to claim 2, wherein the first memory cells are the odd-numbered memory cells, and
wherein the second memory cells are the even-numbered memory cells.

7. The memory device according to claim 2, wherein a bit at a predetermined position, among the k bits to be stored in each of the plurality of first memory cells, is an erase value, and a bit at the predetermined position, among the k bits to be stored in each of the plurality of second memory cells, is a complement of the erase value.

8. The memory device according to claim 1, wherein the peripheral unit is configured to read data stored in the plurality of memory cells based on 2^{k-1} read voltages, each located between respective threshold voltage distributions.

9. The memory device according to claim 8, wherein the plurality of memory cells includes a plurality of first memory cells and a plurality of second memory cells, and
wherein the peripheral unit is configured to apply a lowest read voltage, among the 2^{k-1} read voltages, to the memory cells and configured to read a bit at a predetermined position, among the k bits stored in each of the plurality of second memory cells, among the plurality of memory cells, according to a result of comparing a threshold voltage of each of the plurality of second memory cells with the lowest read voltage.

10. The memory device according to claim 9, wherein, regardless of a result of applying any of the 2^{k-1} read voltages to the memory cells, the peripheral unit is configured to read, as an erase value, a bit at the predetermined position, among the k bits stored in each of the plurality of first memory cells, among the plurality of memory cells.

11. A memory device comprising:
a plurality of memory cells; and
a peripheral unit configured to control the plurality of memory cells to form n number of threshold voltage distributions when k bits are stored in each of the plurality of memory cells during a normal program operation and configured to control the plurality of memory cells to form m number of threshold voltage distributions when k bits are stored in each of the plurality of memory cells during a fast program operation,
wherein n is greater than m, and
wherein k, n, and m are integers.

12. The memory device according to claim 11, wherein, in the fast program operation, when the k bits to be stored in a memory cell, among the plurality of memory cells, are erase values, the peripheral unit is configured to control the memory cell to be located in a lowest threshold voltage distribution, among the m threshold voltage distributions.

13. The memory device according to claim 11, wherein, in the fast program operation, when a bit at a predetermined position, among the k bits to be stored in a memory cell, among the plurality of memory cells, is a complement of an erase value and remaining bits, which are the k bits excluding the bit at the predetermined position, are erase values, the peripheral unit is configured to control the memory cell to be located in a second lowest threshold voltage distribution, among the m threshold voltage distributions.

14. The memory device according to claim 11, wherein, in the fast program operation, when at least one of remaining bits to be stored in a memory cell, among the plurality of memory cells, which are the k bits excluding a bit at a predetermined position, is a complement of an erase value, the peripheral unit is configured to control the memory cell to be located in any of the m threshold voltage distributions excluding a lowest threshold voltage distribution and a second lowest threshold voltage distribution according to the remaining bits.

15. The memory device according to claim 11, wherein a bit at a predetermined position, among the k bits to be stored in each of a plurality of first memory cells, among the plurality of memory cells, is an erase value, and
wherein a bit at the predetermined position, among the k bits to be stored in each of a plurality of second memory cells, among the plurality of memory cells, is a complement of the erase value.

16. The memory device according to claim 11, wherein the peripheral unit is configured to apply, to the plurality of memory cells, a lowest read voltage, among a plurality of read voltages located between respective threshold voltage distributions and configured to read a bit at a predetermined position, among k bits stored in each of a plurality of second memory cells, among the plurality of memory cells, according to a result of comparing a threshold voltage of each of the plurality of second memory cells with the lowest read voltage.

17. The memory device according to claim 16, wherein the peripheral unit is configured to read, as an erase value, a bit at the predetermined position, among k bits stored in each of first memory cells, among the plurality of memory cells, regardless of a result of applying any of the plurality of read voltages to the memory cells.

18. A storage device comprising:
a controller configured to convert first data into second data, the controller converting, in the first data, a bit at a predetermined position among k bits corresponding to each of a plurality of even-numbered memory cells, among a plurality of target memory cells, into a first value and converting a bit at the predetermined position among k bits corresponding to each of a plurality of odd-numbered memory cells, among the plurality of target memory cells, into a second value, the second value being different from the first value; and
a memory device configured to store the second data in the plurality of target memory cells under the control of the controller,
wherein k is an integer.

19. The storage device according to claim 18, wherein the memory device is configured to store the second data in the plurality of target memory cells by controlling the plurality of target memory cells to form 2^{k-1}+1 threshold voltage distributions.

20. The storage device according to claim 19, wherein the memory device is configured to read the second data stored in the plurality of target memory cells based on 2^{k-1} read voltages located between respective threshold voltage distributions.
